(19) United States
(12) Patent Application Publication
(10) Pub. No.: US 2026/0321546 A1
(43) Pub. Date: Oct. 15, 2026

(54) GAS SUPPLIER, SHOWERHEAD, AND PIPE

(71) Applicant: Tokyo Electron Limited, Tokyo (JP)

(72) Inventor: Jun ENDO, Miyagi (JP)

(73) Assignee: Tokyo Electron Limited, Tokyo (JP)

(21) Appl. No.: 19/690,044

(22) Filed: May 28, 2026

Related U.S. Application Data
(63) Continuation of application No. PCT/JP2024/042447, filed on Dec. 2, 2024.

(30) Foreign Application Priority Data
Dec. 15, 2023 (JP) 2023-212091

(51) Int. Cl. H01J 37/32

(52) U.S. Cl. CPC H01J 37/3244; H01J 2237/334

(57) ABSTRACT

A gas supplier includes a first member formed from a conductive material, a second member formed from a conductive material and set to a potential different from a potential of the first member, and a pipe formed from a dielectric. The pipe allows a gas flow between the first member and the second member. The pipe has a first end received in an opening in the second member. The pipe includes a channel inside extending obliquely with respect to a direction from the first member toward the second member. The channel in the pipe includes, between the first member and the second member, a portion having a smaller cross section in the direction from the first member toward the second member than a portion of the channel in the pipe received in the opening in the second member.

### CROSS-REFERENCE TO RELATED APPLICATIONS

This application is a continuation application of International Application No. PCT/JP2024/042447, filed on Dec. 2, 2024, which claims the benefit of priority of the prior Japanese Patent Application No. 2023-212091, filed on Dec. 15, 2023, the entire contents of which are incorporated herein by reference.

### FIELD

One or more embodiments of the present disclosure relate to a gas supplier, a showerhead, and a pipe.

### BACKGROUND

WO publication 2003/046969 discloses a plasma etching apparatus 100 that applies radio-frequency (RF) power to a lower electrode 110 of a pair of electrodes facing each other in an airtight process chamber 102 and generates plasma from a process gas introduced into a space between the electrodes to perform predetermined processing on a surface of a processing target. The plasma etching apparatus 100 includes a heat transfer gas supply 120 including a gas supply pipe 162 for a heat transfer gas and a block 164 for the gas supply pipe. The heat transfer gas supply 120 supplies a heat transfer gas for controlling the temperature of the processing target to a predetermined temperature into a small space S between the processing target and an electrostatic chuck 112 that clamps the processing target. The heat transfer gas supply pipe 162 extends obliquely with respect to the direction of an electric field generated from the RF power applied to the electrodes.

One or more aspects of the present disclosure are directed to a gas supplier, a showerhead, and a pipe that increase the conductance of a channel while preventing electric discharge of a gas in the channel.

### SUMMARY

A gas supplier according to one aspect of the present disclosure includes a first member, a second member, and a pipe. The first member is formed from a conductive material. The second member is formed from a conductive material. The second member is set to a potential different from a potential of the first member. The pipe is formed from a dielectric. The pipe allows a gas flow between the first member and the second member. The pipe has a first end received in an opening in the second member. The pipe includes a channel inside extending obliquely with respect to a direction from the first member toward the second member. The channel in the pipe includes, between the first member and the second member, a portion having a smaller cross section in the direction from the first member toward the second member than a portion of the channel in the pipe received in the opening in the second member.

### BRIEF DESCRIPTION OF DRAWINGS

FIG. 1 is a schematic diagram of an example plasma processing system.

FIG. 2 is an enlarged cross-sectional view of a pipe, illustrating an example structure.

FIG. 3 is a diagram of a pipe in a first reference example, illustrating an example distribution of equipotential lines.

FIG. 4 is a diagram of a pipe in a second reference example, illustrating an example distribution of equipotential lines.

FIG. 5 is a graph showing an example relationship between the distance from a top plate and a potential.

FIG. 6 is a graph showing an example relationship between the distance from the top plate and the length of a cross section of a channel.

FIG. 7 is a diagram of a pipe according to one or more embodiments, illustrating an example distribution of equipotential lines.

FIG. 8 is a table showing the comparison of the conductance of the pipes in the first reference example, the second reference example, and one or more embodiments.

FIG. 9 is a graph showing another example relationship between the distance from the top plate and the length of the cross section of the channel.

FIG. 10 is an enlarged cross-sectional view of the pipe, illustrating another example structure.

FIG. 11 is an enlarged cross-sectional view of the pipe, illustrating another example channel.

### DETAILED DESCRIPTION

A gas supplier, a showerhead, and a pipe according to one or more embodiments of the present disclosure will be described below in detail with reference to the drawings. The one or more embodiments described below do not limit the gas supplier, the showerhead, and the pipe according to the present disclosure.

When a pipe is placed between two conductors with a potential difference to allow a gas flow through the pipe, a gas channel having a larger cross section in a direction of an electric field generated by the potential difference may cause molecules of the gas flowing through the channel to be accelerated by the electric field. The gas may then start discharging electricity. This discharge occurs when the mean free path of gas molecules exceeds the channel's effective dimension in the field direction, leading to ionization. Electric discharge in the pipe may damage the inner wall of the pipe and cause particles resulting from the damaged portion of the inner wall to scatter into a process chamber together with the gas. To prevent such discharge in the pipe, the gas channel may have a smaller cross section in the direction of the electric field.

However, the channel with a smaller cross section in the direction of the electric field may have a lower conductance in the channel, causing difficulties in increasing the flow rate of the gas flowing through the pipe or promptly switching the gas in the space in which the gas is supplied through the pipe.

One or more aspects of the present disclosure are directed to a technique for increasing the conductance of the channel while preventing electric discharge of the gas in the channel.

### Structure of Plasma Processing System

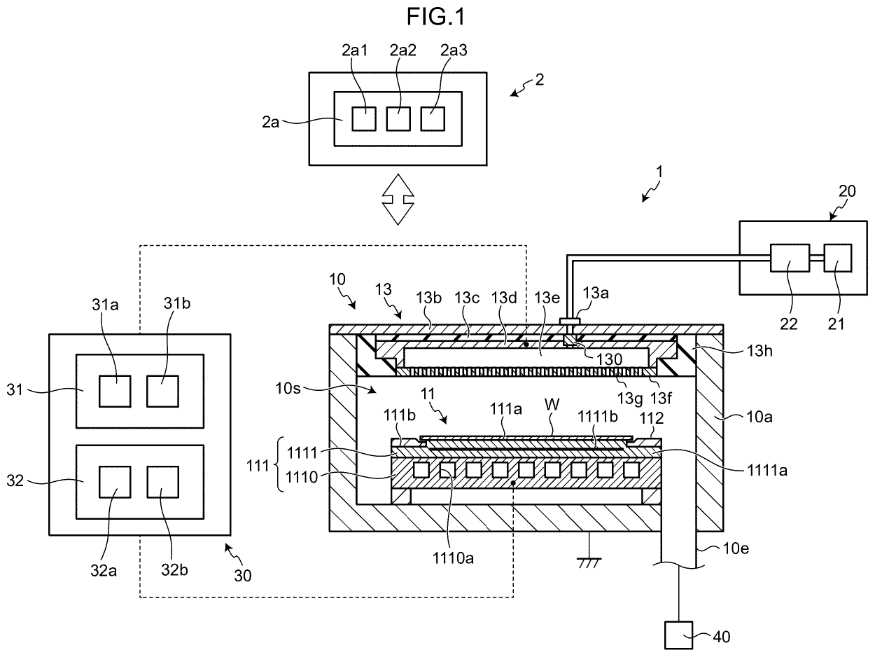

An example structure of a plasma processing system will now be described. FIG. 1 is a schematic diagram of an example plasma processing system. The plasma processing system includes a capacitively coupled plasma processing apparatus 1 and a controller 2. The capacitively coupled plasma processing apparatus 1 includes a plasma processing chamber 10, a gas supply 20, a power supply 30, and an exhaust system 40. The plasma processing apparatus 1 further includes a substrate support 11 and a gas guide unit. The gas guide unit allows at least one process gas to be introduced into the plasma processing chamber 10. The gas guide unit includes a showerhead 13. The substrate support 11 is located in the plasma processing chamber 10. The showerhead 13 is located above the substrate support 11. In one embodiment, the showerhead 13 defines at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 has at least one gas inlet for supplying at least one process gas into the plasma processing space 10s and at least one gas outlet for discharging the gas from the plasma processing space 10s. The plasma processing chamber 10 is formed from a conductor such as aluminum and is grounded. The showerhead 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one radio-frequency (RF)/direct current (DC) electrode coupled to an RF power supply 31 or a DC power supply 32, or both (described later) may be located inside the ceramic member 1111a. In this case, at least one RF/DC electrode functions as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may function as multiple lower electrodes. The electrostatic electrode 1111b may also function as a lower electrode. The substrate support 11 thus includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate W to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The showerhead 13 introduces at least one process gas from the gas supply 20 into the plasma processing space 10s. The showerhead 13 is an example of the gas supplier. The showerhead 13 includes at least one gas inlet 13a, a top plate 13b, an insulating member 13c, a holder 13d, at least one gas-diffusion compartment 13e, a shower plate 13f, and a pipe 130. The top plate 13b is an example of a first member. The holder 13d is an example of a second member.

The shower plate 13f has gas guides 13g that are multiple through-holes. The top plate 13b is formed from a conductive material such as aluminum and is grounded through the sidewall 10a of the plasma processing chamber 10. The holder 13d and the shower plate 13f are formed from a conductive material such as aluminum. The insulating member 13c is located between a lower surface 13b1 of the top plate 13b and an upper surface 13d1 of the holder 13d to insulate the top plate 13b from the holder 13d. The holder 13d is supported on the sidewall 10a of the plasma processing chamber 10 with an insulating member 13h. The holder 13d and the plasma processing chamber 10 are insulated from each other with the insulating member 13h. The holder 13d holds the shower plate 13f in a detachable manner. The holder 13d is coupled to the power supply 30. The holder 13d and the shower plate 13f are maintained at a predetermined potential (e.g., −1.2 kV).

The process gas supplied to the gas inlet 13a is supplied into the gas-diffusion compartment 13e through the pipe 130. The process gas supplied into the gas-diffusion compartment 13e diffuses through the gas-diffusion compartment 13e, and is introduced into the plasma processing space 10s through the gas guides 13g in the shower plate 13f. The holder 13d and the shower plate 13f function as at least one upper electrode. In addition to the showerhead 13, the gas guide unit may include one or more side gas injectors (SGIs) installed in one or more openings in the sidewall 10a.

The gas supply 20 may include at least one gas source 21 and at least one flow controller 22. In one embodiment, the gas supply 20 supplies at least one process gas from each gas source 21 to the showerhead 13 through the corresponding flow controller 22. The flow controller 22 may be, for example, a mass flow controller or a pressure-based flow controller. The gas supply 20 may further include one or more flow rate modulators that cause at least one process gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This generates plasma from at least one process gas supplied into the plasma processing space 10s. The RF power supply 31 may thus function as at least a part of a plasma generator that generates plasma from one or more process gases in the plasma processing chamber 10. A bias RF signal is provided to at least one lower electrode to generate a bias potential in the substrate W, thus drawing ions in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The one or more generated source RF signals are provided to at least one lower electrode or at least one upper electrode, or both.

The second RF generator 31b is coupled to at least one lower electrode through at least one impedance matching circuit and generates a bias RF signal (bias RF power). The bias RF signal may have a frequency that is the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one lower electrode. In various embodiments, at least one of the source RF signal or the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first bias DC signal is applied to at least one lower electrode. In one embodiment, the second DC generator 32b is coupled to at least one upper electrode and generates a second DC signal. The generated second DC signal is applied to at least one upper electrode.

In various embodiments, at least one of the first DC signal or the second DC signal may be pulsed. In this case, the sequence of voltage pulses is applied to at least one lower electrode or at least one upper electrode, or both. The voltage pulses may have a rectangular, trapezoidal, triangular pulse waveform, or a combination of these pulse waveforms. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31 or may include the first DC generator 32a in place of the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

The controller 2 processes computer-executable instructions that cause the plasma processing apparatus 1 to perform various steps described in one or more embodiments of the present disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading a program from the storage 2a2 and executing the loaded program. This program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

### Structure of Pipe 130

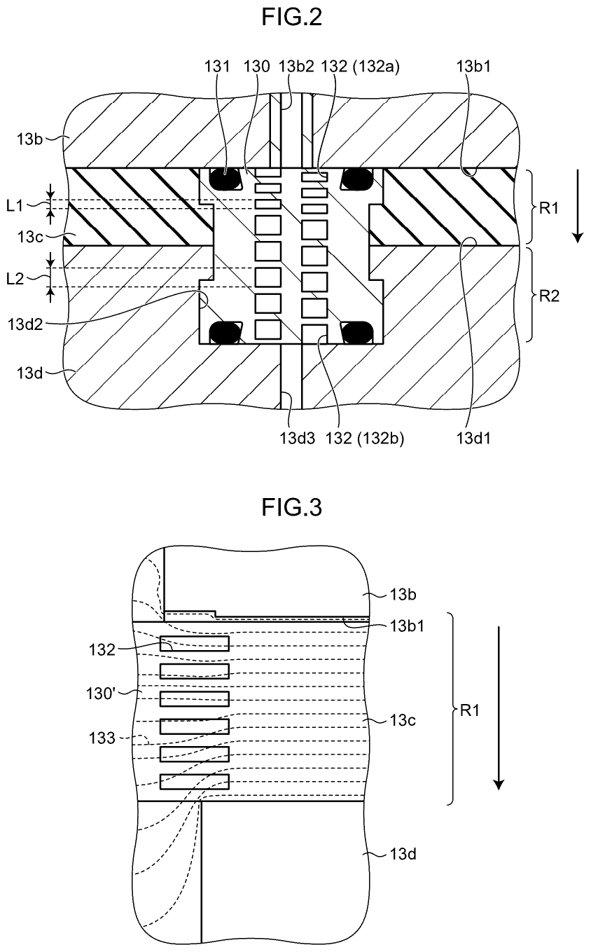

FIG. 2 is an enlarged cross-sectional view of the pipe 130, illustrating an example structure. In the present embodiment, the pipe 130 is formed from a dielectric such as polyimide or polychlorotrifluoroethylene (PCTFE), and is located between the top plate 13b and the holder 13d. In the present embodiment, the pipe 130 has a first end adjacent to the holder 13d. The first end is received in an opening 13d2 in the holder 13d. Sealing members 131 such as O-rings are each located between the top plate 13b and the pipe 130 and between the holder 13d and the pipe 130.

The pipe 130 includes a channel 132 inside through which a gas flows. The channel 132 extends obliquely with respect to the direction from the top plate 13b toward the holder 13d (a direction indicated by an arrow in FIG. 2). In the present embodiment, the channel 132 extends helically in the pipe 130. The channel 132 has a first end adjacent to the holder 13d and a second end adjacent to the top plate 13b. The first end is connected to the gas-diffusion compartment 13e through a channel 13d3. The second end is connected to the gas inlet 13a through a channel 13b2 in the gas inlet 13a.

The channel 132 in the pipe 130 includes, between the top plate 13b and the holder 13d, a portion having a cross section having a length L1 smaller in the direction indicated by the arrow in FIG. 2 than a length L2 of a cross section of a portion of the channel 132 in the pipe 130 received in the opening 13d2 in the holder 13d. In the example in FIG. 2, a channel portion 132a of the pipe 130 corresponding to an area R1 in FIG. 2 has a cross section having the length L1 smaller in the direction indicated by the arrow in FIG. 2 than the length L2 of the cross section of a channel portion 132b of the pipe 130 received in the opening 13d2 in the holder 13d (a portion corresponding to an area R2 in FIG. 2). For example, the channel 132 in the pipe 130 has a cross section having a length in the direction indicated by the arrow in FIG. 2 continuously increasing from the top plate 13b to the holder 13d along the channel. The channel 132 in the portion of the pipe 130 corresponding to the area R1 in FIG. 2 may include a portion having a cross section having substantially the same length in the direction indicated by the arrow in FIG. 2 as the cross section of the channel portion 132b of the pipe 130 received in the opening 13d2 in the holder 13d.

In the present embodiment, the channel 132 has a cross section having a length in the direction indicated by the arrow in FIG. 2 to cause a potential difference between a wall surface of the channel 132 adjacent to the top plate 13b and a wall surface of the channel 132 adjacent to the holder 13d to be smaller than a discharge inception voltage of an Ar gas. Among gases, an Ar gas has a low discharge inception voltage. The channel 132 can have a cross section having a length in the direction indicated by the arrow in FIG. 2 set to avoid electric discharge of an Ar gas, thus reducing electric discharge in the channel 132 when an Ar gas or other gas flows through the channel 132.

### First Reference Example

In a first reference example, a pipe 130′ is located in the area R1 alone between the top plate 13b and the holder 13d. The pipe 130′ has a first end not received in an opening in the holder 13d. FIG. 3 is a diagram of the pipe 130′ in the first reference example, illustrating an example distribution of equipotential lines 133. FIG. 3 simply illustrates a half of the pipe 130′ without illustrating the sealing members 131.

As illustrated in FIG. 3, the pipe 130′ in the first reference example has the equipotential lines 133 with a higher density. Thus, the channel 132 having a larger cross section in the direction from the top plate 13b toward the holder 13d (in a direction indicated by the arrow in FIG. 3) may have a larger potential difference between the wall surface of the channel 132 adjacent to the top plate 13b and the wall surface of the channel 132 adjacent to the holder 13d. When the potential difference between the wall surface of the channel 132 adjacent to the top plate 13b and the wall surface of the channel 132 adjacent to the holder 13d exceeds a discharge inception voltage of the gas flowing through the channel 132, electric discharge may occur in the channel 132.

To avoid electric discharge of a gas in the channel 132, the channel 132 is to have a cross section smaller in the direction indicated by the arrow in FIG. 3. With a smaller cross section in the direction of the arrow in FIG. 3, the channel 132 may have a lower conductance, causing difficulties in increasing the flow rate of the gas flowing through the channel 132 or promptly switching the gas in the plasma processing space 10s into which the gas is supplied through the channel 132.

### Second Reference Example

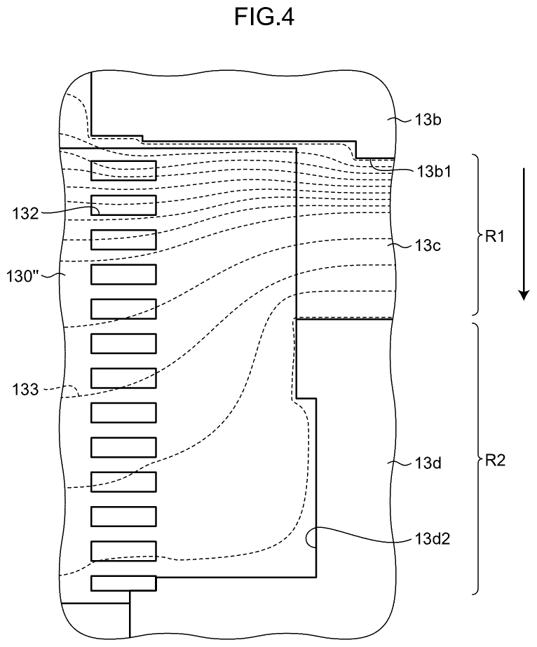

In a second reference example, a pipe 130″ includes a portion located in the area R1 between the top plate 13b and the holder 13d and a portion received in the opening 13d2 in the holder 13d. FIG. 4 is a diagram of the pipe 130″ in the second reference example, illustrating an example distribution of the equipotential lines 133. FIG. 4 simply illustrates a half of the pipe 130″ without illustrating the sealing members 131.

As illustrated in FIG. 4, the pipe 130″ in the second reference example has the equipotential lines 133 with a lower density in a portion corresponding to the area R2 in FIG. 4 than in a portion corresponding to the area R1 in FIG. 4. In the example in FIG. 4, the equipotential lines 133 extend through the portion of the pipe 130″ corresponding to the area R2 in FIG. 4. Thus, the pipe 130″ has, in a portion closer to the holder 13d in the area R1 in FIG. 4, equipotential lines 133 with a lower density than in a portion adjacent to the top plate 13b in the area R1 in FIG. 4.

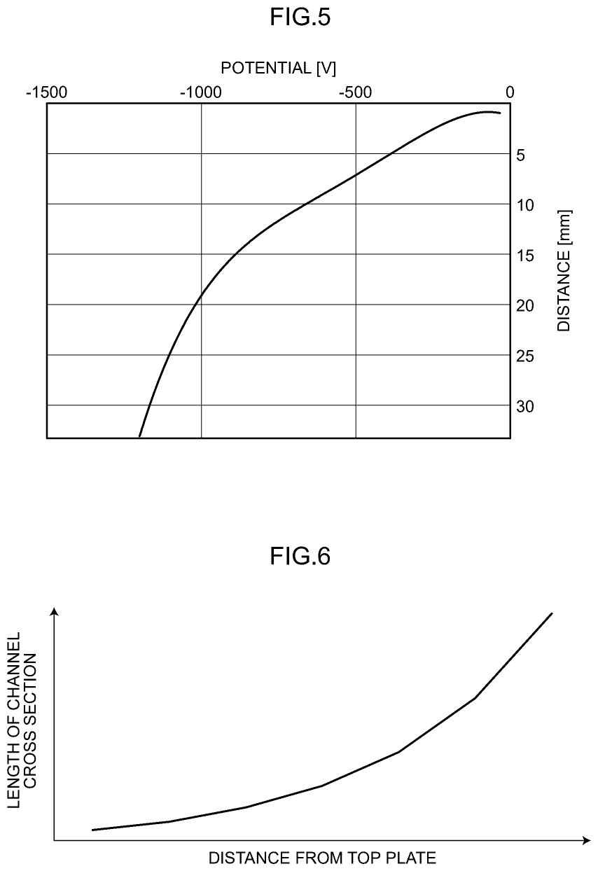

The pipe 130″ in the second reference example has the relationship between the distance from the top plate 13b and the potential as shown in, for example, FIG. 5. The distance is from the surface of the top plate 13b closer to the holder 13d in the direction indicated by the arrow in FIG. 4. In the example in FIG. 5, the holder 13d receives a DC voltage of −1.2 kV, causing a potential difference of 1.2 kV between the top plate 13b and the holder 13d.

As shown in FIG. 5, a change in the potential with respect to a change in the distance from the holder 13d is larger at a position closer to the holder 13d and is smaller at a position farther from the holder 13d. In other words, the electric field changes by a greater degree at a position closer to the holder 13d and by a lesser degree at a position away from the holder 13d.

The length of the cross section of the channel 132 in the direction of the arrow in FIG. 4 is plotted with respect to the distance from the top plate 13b as shown in, for example, FIG. 6. The length is set to cause a potential difference to be constant between the wall surface of the channel 132 adjacent to the top plate 13b and the wall surface of the channel 132 adjacent to the holder 13d. As shown in FIG. 6, the length of the cross section of the channel 132 increases at a position farther from the top plate 13b The length is set to cause a potential difference to be constant between the wall surface of the channel 132 adjacent to the top plate 13b and the wall surface of the channel 132 adjacent to the holder 13d. In other words, the length of the cross section of the channel 132 in the direction of the arrow in FIG. 4 can be increased at a position farther from the top plate 13b to a degree smaller than or equal to the length of the cross section of the channel 132 shown in FIG. 6 in the second reference example.

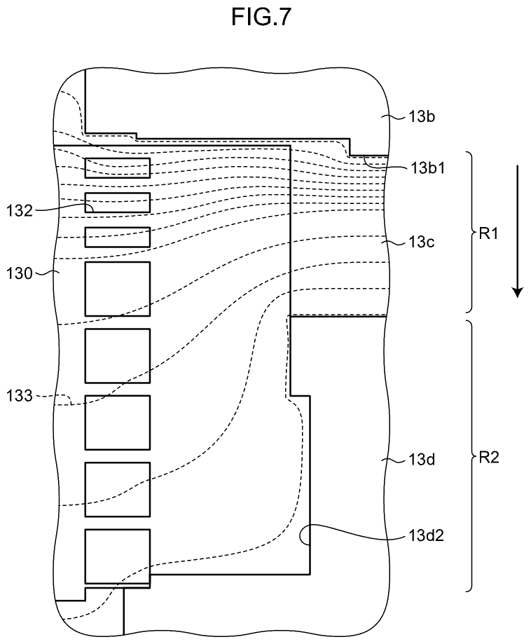

FIG. 7 is a diagram of the pipe 130 according to the present embodiment, illustrating an example distribution of the equipotential lines 133. FIG. 7 simply illustrates a half of the pipe 130 without illustrating the sealing members 131. In the present embodiment, as illustrated in, for example, FIG. 7, the channel 132 has a larger cross section in the direction from the top plate 13b toward the holder 13d (in a direction indicated by the arrows in FIG. 7) at a position farther from the holder 13d. This can increase the cross-sectional area of the channel 132 within a range in which the potential difference between the wall surface of the channel 132 adjacent to the top plate 13b and the wall surface of the channel 132 adjacent to the holder 13d is smaller than or equal to a predetermined value, thus increasing the conductance of the channel 132.

### Comparison of Conductance of Channel 132

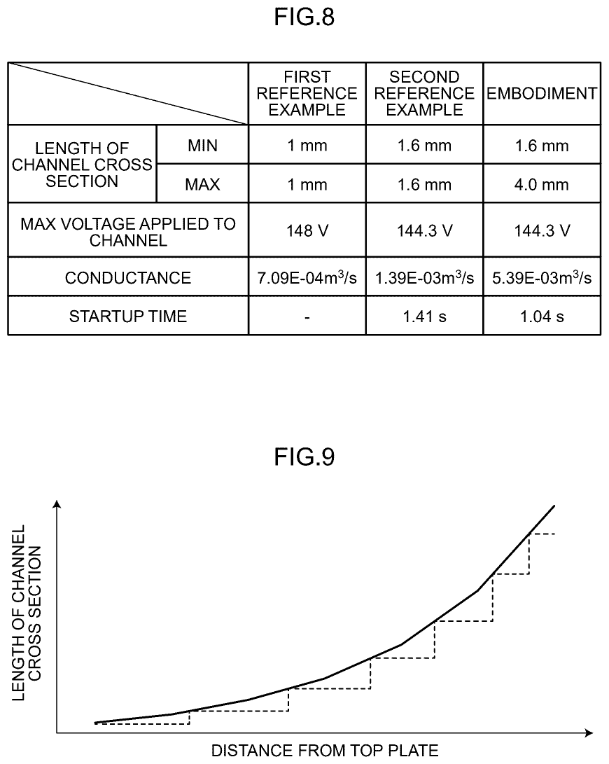

FIG. 8 is a table showing the comparison of the conductance of the pipes in the first reference example, the second reference example, and one or more embodiments. For the pipe 130′ in the first reference example (refer to FIG. 3), the channel 132 has a cross section of 1 mm in the direction from the top plate 13b toward the holder 13d independently of the distance from the top plate 13b, and receives a maximum voltage of 148 V. For the pipe 130″ in the second reference example (refer to FIG. 4), the channel 132 has a cross section of 1.6 mm in the direction from the top plate 13b toward the holder 13d independently of the distance from the holder 13d, and receives a maximum voltage of 144.3 V. For the pipe 130 in the present embodiment (refer to FIGS. 2 and 7), the channel 132 has a cross section with a minimum length of 1.6 mm and a maximum length of 4.0 mm in the direction from the top plate 13b toward the holder 13d, and receives a maximum voltage of 144.3 V. In FIG. 8, the cross section of the channel 132 has the length in the direction from the top plate 13b toward the holder 13d set to provide a potential difference smaller than 178 V, which is a discharge inception voltage of an Ar gas, in each of the first reference example, the second reference example, and the present embodiment.

As shown in, for example, FIG. 8, the channel 132 in the present embodiment has the highest conductance among the channels 132 in the first reference example, the second reference example, and the present embodiment. The pipe 130 according to the present embodiment can thus increase the conductance of the channel 132 while preventing electric discharge of the gas in the channel 132. The pipe 130 according to the present embodiment has a smaller startup time taken for introducing a gas with a predetermined flow rate into the plasma processing chamber 10 than the pipe 130″ in the second reference example. The pipe 130 according to the present embodiment can thus promptly switch the gas in the plasma processing chamber 10 through the pipe 130. To increase the conductance of the channel 132, the length of the cross section of the channel 132 (the width of the channel 132) may be increased in a direction intersecting with the direction from the top plate 13b toward the holder 13d.

One or more embodiments has been described above. As described above, the showerhead 13 according to the present embodiment includes the top plate 13b formed from a conductive material, the holder 13d formed from a conductive material and set to a potential different from the potential of the top plate 13b, and the pipe 130 formed from a dielectric to allow a gas flow between the top plate 13b and the holder 13d. The pipe 130 has the first end received in the opening 13d2 in the holder 13d. The pipe 130 includes the channel inside extending obliquely with respect to the direction from the top plate 13b toward the holder 13d. The channel 132 in the pipe 130 includes, between the top plate 13b and the holder 13d, a portion having a smaller cross section in the direction from the top plate 13b toward the holder 13d than a portion of the channel 132 in the pipe 130 received in the opening 13d2 in the holder 13d. This structure increases the conductance of the channel 132 while preventing electric discharge of the gas in the channel 132.

In the above embodiment, the channel 132 in the pipe 130 has a cross section having the length in the direction from the top plate 13b toward the holder 13d continuously increasing from the top plate 13b to the holder 13d in a direction in which the channel 132 extends. This structure reduces stagnation of a gas in the channel 132 and allows a smooth gas flow.

In the above embodiment, the channel 132 extends helically in the pipe 130. This structure downsizes the pipe 130.

In the above embodiment, the channel 132 in the pipe 130 has a cross section having the length in the direction from the top plate 13b toward the holder 13d to cause the potential difference between the wall surface of the channel 132 adjacent to the top plate 13b and the wall surface of the channel 132 adjacent to the holder 13d to be smaller than the discharge inception voltage of an Ar gas. Among gases, an Ar gas has a low discharge inception voltage. The pipe 130 according to the present embodiment can thus increase the conductance of the channel 132 while preventing any gas flowing through the channel 132 from undergoing electric discharge in the channel 132.

In the above embodiment, the pipe 130 is formed from polyimide. The pipe 130 can thus be produced easily.

In the above embodiment, the showerhead 13 includes the top plate 13b, the holder 13d, the shower plate 13f, and the pipe 130. The top plate 13b is formed from a conductive material and is grounded. The holder 13d is formed from a conductive material and is insulated from the top plate 13b. The shower plate 13f is formed from a conductive material and has multiple through-holes. The shower plate 13f is held by the holder 13d. The pipe 130 is formed from a dielectric. The pipe 130 is located between the top plate 13b and the holder 13d to supply a gas to the gas-diffusion compartment 13e between the holder 13d and the shower plate 13f through the top plate 13b. The top plate 13b and the shower plate 13f receive a voltage with a predetermined magnitude. The pipe 130 has the first end received in the opening 13d2 in the holder 13d. The pipe 130 includes the channel inside extending obliquely with respect to the direction from the top plate 13b toward the holder 13d. The channel 132 in the pipe 130 includes, between the top plate 13b and the holder 13d, a portion having a smaller cross section in the direction from the top plate 13b toward the holder 13d than a portion of the channel 132 in the pipe 130 received in the opening 13d2 in the holder 13d. This structure increases the conductance of the channel 132 while preventing electric discharge of the gas in the channel 132.

### Others

The technique according to one or more embodiments described in the present application is not limited to one or more embodiments described above, and may be changed variously within the scope of the present disclosure.

In the above embodiment, for example, the channel 132 in the pipe 130 has a cross section having a length in the direction from the top plate 13b toward the holder 13d continuously increasing from the top plate 13b to the holder 13d along the channel. However, the technique according to one or more embodiments of the present disclosure is not limited to this example. In another embodiment, the channel 132 may have a cross section having the length in the direction from the top plate 13b toward the holder 13d increasing in a stepwise manner from the top plate 13b to the holder 13d along the channel as indicated by, for example, a dashed line in FIG. 9. The pipe 130 can thus be manufactured easily.

Although the pipe 130 includes the single channel 132 in the above embodiment, the technique according to one or more embodiments of the present disclosure is not limited to this example. The pipe 130 may include multiple channels 132. This structure allows the single pipe 130 to supply multiple different gases. The same gas may flow through the multiple channels 132 in the pipe 130.

Although the pipe 130 has the first end received in the opening 13d2 in the holder 13d in the above embodiment, the technique according to one or more embodiments of the present disclosure is not limited to this example. In another embodiment, the pipe 130 may have the second end received in the opening in the top plate 13b. The channel 132 in the pipe 130 includes, between the top plate 13b and the holder 13d, a portion having a smaller cross section in the direction from the top plate 13b toward the holder 13d than the portion of the channel 132 in the pipe 130 received in the opening in the top plate 13b. This structure also reduces the electric field applied to the portion of the channel 132 in the pipe 130 received in the opening in the top plate 13b. The channel 132 in the pipe 130 in the portion received in the opening in the top plate 13b can thus have a larger cross section in the direction from the top plate 13b toward the holder 13d. This structure can increase the conductance of the channel 132. The pipe 130 may have the first end received in the opening 13d2 in the holder 13d and the second end received in the opening in the top plate 13b.

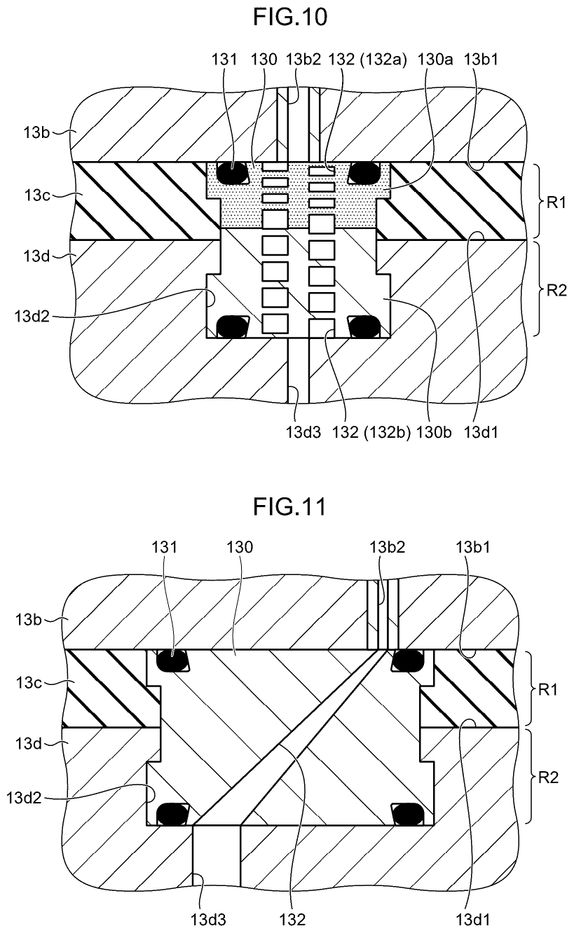

Although the pipe 130 is formed from a single dielectric material in the above embodiment, the technique according to one or more embodiments of the present disclosure is not limited to this example. The pipe 130 may be formed from multiple materials with different dielectric constants. As illustrated in, for example, FIG. 10, the pipe 130 may be formed from materials with different dielectric constants. In the example in FIG. 10, the pipe 130 includes a first dielectric 130a and a second dielectric 130b having a higher dielectric constant than the first dielectric 130a. In the example in FIG. 10, the pipe 130 includes, between the top plate 13b and the holder 13d (in the area R1), at least a portion formed from the first dielectric 130a. This structure can reduce the electric field applied to the channel 132 in the pipe 130 in the area R1 compared with the pipe 130 formed from a single dielectric. The channel 132 in the area R1 can thus have a larger cross section in the direction from the top plate 13b toward the holder 13d. This structure can increase the conductance of the channel 132.

Although the pipe 130 includes the channel 132 extending helically in the above embodiment, the technique according to one or more embodiments of the present disclosure is not limited to this example. The channel 132 in the pipe 130 may be in any shape that extends obliquely with respect to the direction from the top plate 13b toward the holder 13d, rather than extending helically. The channel 132 may be straight as illustrated in, for example, FIG. 11. In the example in FIG. 11 as well, the channel 132 has a cross section having the length in the direction from the top plate 13b toward the holder 13d increasing gradually from the top plate 13b to the holder 13d along the channel. In the example in FIG. 11 as well, the channel 132 has a cross section having the length in the direction from the top plate 13b toward the holder 13d to cause the potential difference between the wall surface of the channel 132 adjacent to the top plate 13b and the wall surface of the channel 132 adjacent to the holder 13d to be smaller than the discharge inception voltage of an Ar gas. The channel 132 with such a shape can also have an increased conductance while preventing electric discharge of the gas in the channel 132.

Although the pipe 130 is located inside the showerhead 13 in the above embodiment, the technique according to one or more embodiments of the present disclosure is not limited to this example. The pipe may be located in a portion other than the showerhead 13 to allow a gas flow between two conductive members with a potential difference, and may be, for example, a pipe for supplying a heat transfer gas between the substrate W and the ESC 1111.

Although the plasma processing apparatus 1 uses capacitively coupled plasma (CCP) for processing in the above embodiment as an example plasma source, the plasma source is not limited to CCP. Plasma sources other than CCP include, for example, inductively coupled plasma (ICP), microwave-excited surface wave plasma (SWP), electron cyclotron resonance plasma (ECP), and helicon wave excited plasma (HWP).

The technique according to various aspects and embodiments of the present disclosure can increase the conductance of the channel while preventing electric discharge of the gas in the channel.

The one or more embodiments described herein are illustrative in all aspects and should not be construed to be restrictive. The above embodiments may be implemented in various forms. The components in the above embodiments may be eliminated, substituted, or modified in various forms without departing from the spirit and scope of the appended claims. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

Appendixes according to the above embodiments will be further described below.

### (Appendix 1)

A gas supplier, comprising:
a first member comprising a conductive material;
a second member comprising a conductive material, the second member being set to a potential different from a potential of the first member; and
a pipe comprising a dielectric, the pipe allowing a gas flow between the first member and the second member,
wherein the pipe has a first end received in an opening in the second member,
the pipe includes a channel inside extending obliquely with respect to a direction from the first member toward the second member, and
the channel in the pipe includes, between the first member and the second member, a portion having a smaller cross section in the direction from the first member toward the second member than a portion of the channel in the pipe received in the opening in the second member.

### (Appendix 2)

The gas supplier according to appendix 1, wherein
the channel in the pipe has a cross section having a length in the direction from the first member toward the second member continuously increasing from the first member to the second member.

### (Appendix 3)

The gas supplier according to appendix 1, wherein
the channel in the pipe has a cross section having a length in the direction from the first member toward the second member increasing in a stepwise manner from the first member to the second member.

### (Appendix 4)

The gas supplier according to any one of appendixes 1 to 3, wherein
the channel extends helically in the pipe.

### (Appendix 5)

The gas supplier according to any one of appendixes 1 to 4, wherein
the pipe includes a plurality of the channels.

### (Appendix 6)

The gas supplier according to any one of appendixes 1 to 5, wherein
the pipe has a second end received in an opening in the first member, and
the channel in the pipe includes, between the first member and the second member, a portion having a smaller cross section in the direction from the first member toward the second member than a portion of the channel in the pipe received in the opening in the first member.

### (Appendix 7)

The gas supplier according to any one of appendixes 1 to 6, wherein
the channel in the pipe has a cross section having a length in the direction from the first member toward the second member to cause a potential difference between a wall surface of the channel adjacent to the first member and a wall surface of the channel adjacent to the second member to be smaller than a discharge inception voltage of an Ar gas.

### (Appendix 8)

The gas supplier according to any one of appendixes 1 to 7, wherein
the pipe comprises polyimide.

### (Appendix 9)

The gas supplier according to any one of appendixes 1 to 7, wherein
the pipe comprises a first dielectric and a second dielectric, the second dielectric having a higher dielectric constant than the first dielectric,
the pipe includes, between the first member and the second member, at least a portion comprising the first dielectric, and
the first end of the pipe received in the second member comprises the second dielectric.

### (Appendix 10)

A showerhead, comprising:
a top plate comprising a conductive material and being grounded;
a holder comprising a conductive material and being insulated from the top plate;
a shower plate comprising a conductive material and having a plurality of through-holes, the shower plate being held by the holder; and
a pipe comprising a dielectric, the pipe being located between the top plate and the holder and supplying a gas to a space between the holder and the shower plate through the top plate,
wherein the holder and the shower plate receive a voltage with a predetermined magnitude,
the pipe has a first end received in an opening in the holder,
the pipe includes a channel inside extending obliquely with respect to a direction from the top plate toward the holder, and
the channel in the pipe includes, between the top plate and the holder, a portion having a smaller cross section in the direction from the top plate toward the holder than a portion of the channel in the pipe received in the opening in the holder.

### (Appendix 11)

The shower head according to appendix 10, wherein
the channel in the pipe has a cross section having a length in the direction from the top plate toward the holder continuously increasing from the top plate to the holder.

### (Appendix 12)

The shower head according to appendix 10, wherein
the channel in the pipe has a cross section having a length in the direction from the top plate toward the holder increasing in a stepwise manner from the top plate to the holder.

### (Appendix 13)

The shower head according to appendix 10, wherein
the channel extends helically in the pipe.

### (Appendix 14)

The shower head according to appendix 10, wherein
the pipe includes a plurality of the channels.

### (Appendix 15)

The shower head according to appendix 10, wherein
the pipe has a second end received in an opening in the top plate, and
the channel in the pipe includes, between the top plate and the holder, a portion having a smaller cross section in the direction from the top plate toward the holder than a portion of the channel in the pipe received in the opening in the top plate.

### (Appendix 16)

The shower head according to appendix 10, wherein
the channel in the pipe has a cross section having a length in the direction from the top plate toward the holder to cause a potential difference between a wall surface of the channel adjacent to the top plate and a wall surface of the channel adjacent to the holder to be smaller than a discharge inception voltage of an Ar gas.

### (Appendix 17)

The shower head according to appendix 10, wherein
the pipe comprises polyimide.

### (Appendix 18)

The shower head according to appendix 10, wherein
the pipe comprises a first dielectric and a second dielectric, the second dielectric having a higher dielectric constant than the first dielectric,
the pipe includes, between the top plate and the holder, at least a portion comprising the first dielectric, and
the first end of the pipe received in the holder comprises the second dielectric.

### (Appendix 19)

The shower head according to appendix 10, wherein
the pipe supplies the gas to a gas-diffusion compartment between the holder and the shower plate through the top plate.

### (Appendix 20)

A pipe for allowing a gas flow between a first member and a second member, the first member comprising a conductive material, the second member comprising a conductive material and set to a potential different from a potential of the first member, the pipe comprising:
a dielectric;
a first end received in an opening in the second member; and
a channel inside extending obliquely with respect to a direction from the first member toward the second member,
wherein the channel in the pipe includes, between the first member and the second member, a portion having a smaller cross section in the direction from the first member toward the second member than a portion of the channel in the pipe received in the opening in the second member.

What is claimed is

1. A gas supplier, comprising:
a first member comprising a conductive material;
a second member comprising a conductive material, the second member being set to a potential different from a potential of the first member; and
a pipe comprising a dielectric, the pipe allowing a gas flow between the first member and the second member,
wherein the pipe has a first end received in an opening in the second member,
the pipe includes a channel inside extending obliquely with respect to a direction from the first member toward the second member, and
the channel in the pipe includes, between the first member and the second member, a portion having a smaller cross section in the direction from the first member toward the second member than a portion of the channel in the pipe received in the opening in the second member.

2. The gas supplier according to claim 1, wherein
the channel in the pipe has a cross section having a length in the direction from the first member toward the second member continuously increasing from the first member to the second member.

3. The gas supplier according to claim 1, wherein
the channel in the pipe has a cross section having a length in the direction from the first member toward the second member increasing in a stepwise manner from the first member to the second member.

4. The gas supplier according to claim 1, wherein
the channel extends helically in the pipe.

5. The gas supplier according to claim 1, wherein
the pipe includes a plurality of the channels.

6. The gas supplier according to claim 1, wherein
the pipe has a second end received in an opening in the first member, and
the channel in the pipe includes, between the first member and the second member, a portion having a smaller cross section in the direction from the first member toward the second member than a portion of the channel in the pipe received in the opening in the first member.

7. The gas supplier according to claim 1, wherein
the channel in the pipe has a cross section having a length in the direction from the first member toward the second member to cause a potential difference between a wall surface of the channel adjacent to the first member and a wall surface of the channel adjacent to the second member to be smaller than a discharge inception voltage of an Ar gas.

8. The gas supplier according to claim 1, wherein
the pipe comprises polyimide.

9. The gas supplier according to claim 1, wherein
the pipe comprises a first dielectric and a second dielectric, the second dielectric having a higher dielectric constant than the first dielectric,
the pipe includes, between the first member and the second member, at least a portion comprising the first dielectric, and
the first end of the pipe received in the second member comprises the second dielectric.

10. A showerhead, comprising:
a top plate comprising a conductive material and being grounded;
a holder comprising a conductive material and being insulated from the top plate;
a shower plate comprising a conductive material and having a plurality of through-holes, the shower plate being held by the holder; and
a pipe comprising a dielectric, the pipe being located between the top plate and the holder and supplying a gas to a space between the holder and the shower plate through the top plate,
wherein the holder and the shower plate receive a voltage with a predetermined magnitude,
the pipe has a first end received in an opening in the holder,
the pipe includes a channel inside extending obliquely with respect to a direction from the top plate toward the holder, and
the channel in the pipe includes, between the top plate and the holder, a portion having a smaller cross section in the direction from the top plate toward the holder than a portion of the channel in the pipe received in the opening in the holder.

11. The shower head according to claim 10, wherein
the channel in the pipe has a cross section having a length in the direction from the top plate toward the holder continuously increasing from the top plate to the holder.

12. The shower head according to claim 10, wherein
the channel in the pipe has a cross section having a length in the direction from the top plate toward the holder increasing in a stepwise manner from the top plate to the holder.

13. The shower head according to claim 10, wherein
the channel extends helically in the pipe.

14. The shower head according to claim 10, wherein
the pipe includes a plurality of the channels.

15. The shower head according to claim 10, wherein
the pipe has a second end received in an opening in the top plate, and
the channel in the pipe includes, between the top plate and the holder, a portion having a smaller cross section in the direction from the top plate toward the holder than a portion of the channel in the pipe received in the opening in the top plate.

16. The shower head according to claim 10, wherein
the channel in the pipe has a cross section having a length in the direction from the top plate toward the holder to cause a potential difference between a wall surface of the channel adjacent to the top plate and a wall surface of the channel adjacent to the holder to be smaller than a discharge inception voltage of an Ar gas.

17. The shower head according to claim 10, wherein
the pipe comprises polyimide.

18. The shower head according to claim 10, wherein
the pipe comprises a first dielectric and a second dielectric, the second dielectric having a higher dielectric constant than the first dielectric,
the pipe includes, between the top plate and the holder, at least a portion comprising the first dielectric, and
the first end of the pipe received in the holder comprises the second dielectric.

19. The shower head according to claim 10, wherein
the pipe supplies the gas to a gas-diffusion compartment between the holder and the shower plate through the top plate.

20. A pipe for allowing a gas flow between a first member and a second member, the first member comprising a conductive material, the second member comprising a conductive material and set to a potential different from a potential of the first member, the pipe comprising:
a dielectric;
a first end received in an opening in the second member; and
a channel inside extending obliquely with respect to a direction from the first member toward the second member,
wherein the channel in the pipe includes, between the first member and the second member, a portion having a smaller cross section in the direction from the first member toward the second member than a portion of the channel in the pipe received in the opening in the second member.
